(19) United States
(12) Patent Application Publication
(10) Pub. No.: US 2010/0209832 A1
(43) Pub. Date: Aug. 19, 2010

(54) MEASUREMENT APPARATUS, EXPOSURE APPARATUS, AND DEVICE FABRICATION METHOD

(75) Inventor: Hideki Matsuda, Kawachi-gun (JP)

Correspondence Address: ROSSI, KIMMS & McDOWELL LLP., 20609 Gordon Park Square, Suite 150, Ashburn, VA, 20147, US

(73) Assignee: CANON KABUSHIKI KAISHA, Tokyo (JP)

(21) Appl. No.: 12/703,314

(22) Filed: Feb. 10, 2010

(30) Foreign Application Priority Data
Feb. 13, 2009 (JP) 2009-031963

(51) Int. Cl. G03F 7/20; G01B 11/02; G03B 27/52

(52) U.S. Cl. 430/30; 356/511; 355/55

(57) ABSTRACT

The present invention provides a measurement apparatus which measures a surface shape of a measurement target surface, the apparatus including an optical system configured to split light from a light source into measurement light and reference light, guide the measurement light onto the measurement target surface, and guide the reference light onto a reference surface, a detection unit configured to detect an intensity of the measurement light reflected by the measurement target surface, an intensity of the reference light reflected by the reference surface, and an interference pattern formed between the measurement light reflected by the measurement target surface and the reference light reflected by the reference surface, and a processing unit configured to obtain a surface shape of the measurement target surface based on an interference signal of the interference pattern detected by the detection unit.

### BACKGROUND OF THE INVENTION

1. Field of the Invention

The present invention relates to a measurement apparatus, an exposure apparatus, and a device fabrication method.

2. Description of the Related Art

An exposure apparatus projects and transfers a pattern formed on a reticle (mask) onto a substrate such as a wafer via a projection optical system. The exposure apparatus measures the surface position of a substrate at a predetermined position on the substrate using a surface shape (surface position) measurement unit of the light oblique-incidence system during exposure (or before exposure), and performs correction to align the substrate surface with an optimum imaging position prior to exposure of the substrate at the predetermined position. In particular, a scanner measures not only the surface position level (focus) of a substrate but also the surface tilt of the substrate in the longitudinal direction (i.e., a direction perpendicular to the scanning direction) of the exposure slit.

Japanese Patent Laid-Open No. 6-260391, U.S. Pat. No. 6,249,351, and PCT(WO) 2006-514744 propose details of such focus and tilt measurement techniques. Japanese Patent Laid-Open No. 6-260391 and U.S. Pat. No. 6,249,351, for example, disclose techniques using optical sensors. PCT(WO) 2006-514744 discloses a technique using a gas gauge sensor which measures the surface position of a substrate by blowing air onto the substrate. Moreover, a technique using a capacitance sensor is proposed.

In recent years, as the wavelength of the exposure light shortens and the NA of the projection optical system increases, the depth of focus extremely decreases. To keep up with this trend, the accuracy of aligning the surface of a substrate to be exposed with an optimum imaging position, that is, the so-called focus accuracy is increasingly becoming stricter. Under the circumstance, one technique for improving the measurement accuracy is attracting a great deal of attention. This technique measures the surface shape (surface position) of a substrate based on an interference pattern (interference signal) formed by interference between light (measurement light) from the substrate surface (measurement target surface) and light (reference light) from a reference surface.

In this technique, light which has a broad wavelength bandwidth and is emitted by a light source is split into two light beams, one light beam enters the measurement target surface, and the other light beam obliquely enters the reference surface. Then, the measurement light reflected by the measurement target surface and the reference light reflected by the reference surface are combined to detect an interference pattern (interference signal) formed by interference between the measurement light and the reference light. An interference signal is detected while driving the measurement target surface in a predetermined direction (level (focus) direction), and the surface shape of the measurement target surface can be obtained based on a change in the detected interference signal.

Techniques of this kind can shorten the coherence length using light with a broad wavelength bandwidth, thereby setting a measurement range wider than that which can be set using monochromatic light. In addition, these techniques can advantageously reduce interference signal errors attributed to a resist (photosensitive agent) applied on the substrate.

Unfortunately, in the prior arts, when the output from the light source fluctuates with time, noise (light amount noise) that mixes in the interference signal increases, so the surface shape measurement accuracy and reproducibility deteriorate. Because the interference signal can be obtained within a certain finite time range, a fluctuation in output from the light source within that time range, in turn, generates a fluctuation in the amount of light at each measurement position (each driving position on the measurement target surface), and the amount of light naturally differs for each measurement point. Thus, the accuracy of obtaining the peak position of the interference signal deteriorates and, eventually, the surface shape measurement accuracy and reproducibility deteriorate.

### SUMMARY OF THE INVENTION

The present invention provides a technique which can measure the surface shape of a measurement target surface with high accuracy and good reproducibility by reducing the influence of a variation in amount of light from a light source on the measurement result.

According to one aspect of the present invention, there is provided a measurement apparatus which measures a surface shape of a measurement target surface, the apparatus including an optical system configured to split light from a light source into measurement light and reference light, guide the measurement light onto the measurement target surface, and guide the reference light onto a reference surface, a detection unit configured to detect an intensity of the measurement light reflected by the measurement target surface, an intensity of the reference light reflected by the reference surface, and an interference pattern formed between the measurement light reflected by the measurement target surface and the reference light reflected by the reference surface, and a processing unit configured to obtain a surface shape of the measurement target surface based on an interference signal of the interference pattern detected by the detection unit, wherein the processing unit obtains the surface shape of the measurement target surface based on at least one of the intensities of the measurement light and the reference light detected by the detection unit and the interference signal of the interference pattern detected by the detection unit.

Further features of the present invention will become apparent from the following description of exemplary embodiments with reference to the attached drawings.

### BRIEF DESCRIPTION OF THE DRAWINGS

FIG. 1 is a schematic view showing the arrangement of a measurement apparatus according to one aspect of the present invention.

FIG. 2 is a graph illustrating an example of an interference signal (white light interference signal) detected by a detection unit of the measurement apparatus shown in FIG. 1.

FIG. 3 is a flowchart for explaining a process of measuring the surface shape of a substrate in the measurement apparatus shown in FIG. 1.

FIG. 4 is a view illustrating an example of the positional relationship between measurement light and reference light on the detection unit (its detection surface) in the measurement apparatus shown in FIG. 1.

FIG. 5 is a view illustrating another example of the positional relationship between the measurement light and the reference light on the detection unit (its detection surface) in the measurement apparatus shown in FIG. 1.

FIG. 6 is a flowchart for explaining another process of measuring the surface shape of a substrate in the measurement apparatus shown in FIG. 1.

FIGS. 7A to 7C are graphs for explaining calculation of a signal in which the influence of a fluctuation in output from a light source is reduced in step S608 of the flowchart shown in FIG. 6.

FIGS. 8A and 8B are graphs showing the intensities of the measurement light and reference light and an interference signal of interference fringes between them, which are detected by the detection unit when the reflectance of the substrate is equal to that of a reference mirror.

FIGS. 9A and 9B are graphs showing the intensities of the measurement light and reference light and an interference signal of interference fringes between them, which are detected by the detection unit when the reflectance of the substrate is lower than that of the reference mirror.

FIGS. 10A and 10B are graphs showing the intensities of the measurement light and reference light and an interference signal of interference fringes between them, which are detected by the detection unit after the light source is adjusted when the reflectance of the substrate is lower than that of the reference mirror.

FIGS. 11A and 11B are graphs showing the intensities of the measurement light and reference light and an interference signal of interference fringes between them, which are detected by the detection unit when the reflectance of the substrate is higher than that of the reference mirror.

FIGS. 12A and 12B are graphs showing the intensities of the measurement light and reference light and an interference signal of interference fringes between them, which are detected by the detection unit after the light source is adjusted when the reflectance of the substrate is higher than that of the reference mirror.

FIG. 13 is a schematic view showing the arrangement of a measurement apparatus according to another aspect of the present invention.

FIGS. 14A and 14B are graphs illustrating an example of the interference signal of interference fringes detected by a detection unit in the measurement apparatus shown in FIG. 13.

FIG. 15 is a schematic view showing the arrangement of a measurement apparatus according to still another aspect of the present invention.

FIG. 16 is a schematic view showing the arrangement of an exposure apparatus according to one aspect of the present invention.

FIG. 17 is a schematic view showing the arrangement of a focus control sensor of the exposure apparatus shown in FIG. 16.

FIG. 18 is a flowchart for explaining the exposure operation of the exposure apparatus shown in FIG. 16.

FIG. 19 is a detailed flowchart of focus calibration sequences in steps S1030 and S1040 of FIG. 18.

FIG. 20 is a view for explaining a first offset and a second offset in the focus calibration sequences.

FIG. 21 is a detailed flowchart of an exposure sequence in step S1050 of FIG. 18.

### DESCRIPTION OF THE EMBODIMENTS

Preferred embodiments of the present invention will be described below with reference to the accompanying drawings. Note that the same reference numerals denote the same members throughout the drawings, and a repetitive description thereof will not be given.

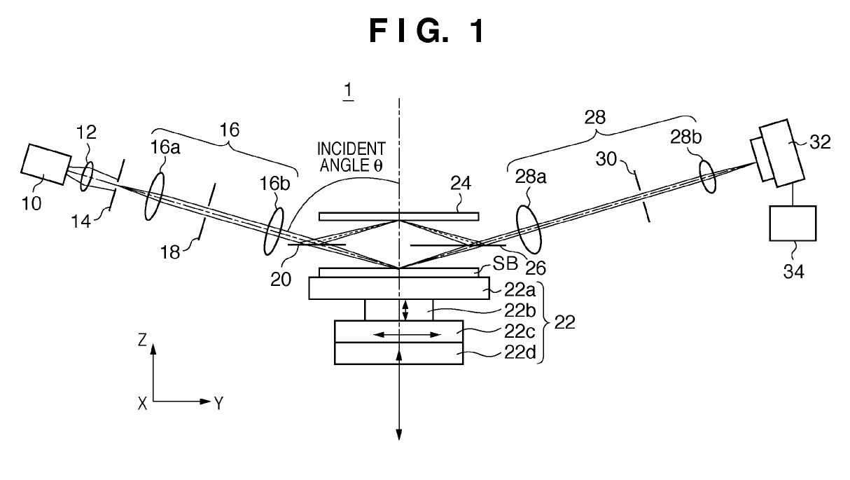

FIG. 1 is a schematic view showing the arrangement of a measurement apparatus 1 according to one aspect of the present invention. The measurement apparatus 1 measures the surface position (the position in the Z-axis direction) of a substrate SB as the measurement target surface, that is, the surface shape of the substrate SB. An example of the substrate SB is a wafer onto which the pattern of a reticle is transferred in an exposure apparatus.

The measurement apparatus 1 includes a light source 10, a condenser lens 12 which converges light from the light source 10, a slit plate 14, an imaging optical system 16 including lenses 16a and 16b, an aperture stop 18, and a beam splitter 20 which splits light from the light source 10 into two light beams. The measurement apparatus 1 also includes a stage system 22 which includes a substrate chuck 22a, Z stage 22b, Y stage 22c, and X stage 22d and supports and drives the substrate SB, and a reference mirror (reference surface) 24. The measurement apparatus 1 also includes a beam splitter 26 which combines the light (measurement light) reflected by the substrate SB and that (reference light) reflected by the reference mirror (reference surface) 24 (i.e., which generates combined light of the measurement light and the reference light), and an imaging optical system 28 including lenses 28a and 28b. The measurement apparatus 1 moreover includes an aperture stop 30, a detection unit 32 including an image sensing device such as a CCD or a CMOS or a light amount detection device such as a photodetector, and a processing unit 34. Note that the processing unit 34 not only participates in the measurement process of the measurement apparatus 1 but also has a function of controlling the overall operation of the measurement apparatus 1.

The operation of the measurement apparatus 1 and the functions of the constituent elements of the measurement apparatus 1 will be explained in detail below.

In this embodiment, the light source 10 is an LED (for example, a white LED) or halogen lamp which emits light with a broad wavelength bandwidth. Light from the light source 10 has a wavelength range of 100 nm or more and, more specifically, a wavelength range of 400 nm to 800 nm. However, when the substrate SB is coated with a resist (photosensitive agent), the substrate SB is not irradiated with light in the range of wavelengths equal to or shorter than those of ultraviolet rays (350 nm) in order to prevent the resist from being exposed to light. In this embodiment, the polarization state of light from the light source 10 is non-polarization or circular polarization.

Light from the light source 10 is converged on the slit plate 14 via the condenser lens 12. The slit plate 14 includes a rectangular transmission region or a mechanical stop, and an image of the transmission region in the slit plate 14 is formed on the substrate SB and reference mirror 24 via the imaging optical system 16. However, the transmission region in the slit plate 14 is not limited to a rectangular shape (slit), and may have a circular shape (pinhole).

The principal ray of the light having passed through the imaging optical system 16 enters the substrate SB at an incident angle θ. Since the beam splitter 20 is inserted in the optical path between the imaging optical system 16 and the substrate SB, nearly a half of the light having passed through the imaging optical system 16 is reflected by the beam splitter 20 and enters the reference mirror 24 at the incident angle θ as well. The beam splitter 20 is, for example, a prism type beam splitter formed from, for example, a metal film or a dielectric multilayer film as a split film, or a pellicle type beam splitter formed from a film (its material is, for example, SiC or SiN) with a thickness as thin as about 1 μm to 5 μm.

As the incident angle θ of the light which enters the substrate SB increases, the reflectance of the upper surface of a thin film (for example, a resist) applied on the substrate SB becomes high relative to that of the lower surface of the thin film (i.e., the interface between the thin film and the substrate SB). In view of this, the incident angle θ is preferably as large as possible, when the surface shape of the thin film applied on the substrate SB is measured. However, the incident angle θ is 70° to 85° in practice because it becomes harder to assemble an optical system as the incident angle θ becomes closer to 90°.

Light which is transmitted through the beam splitter 20 and enters the substrate SB reaches the beam splitter 26 upon being reflected by the substrate SB. On the other hand, light which is reflected by the beam splitter 20 and enters the reference mirror 24 reaches the beam splitter 26 upon being reflected by the reference mirror 24. The light reflected by the substrate SB is called measurement light and that reflected by the reference mirror 24 is called reference light hereinafter. The reference mirror 24 can be, for example, an aluminum plane mirror with a surface accuracy of about 10 nm to 20 nm or a glass plane mirror with nearly the same surface accuracy as that of the aluminum plane mirror.

The measurement light reflected by the substrate SB and the reference light reflected by the reference mirror 24 are combined by the beam splitter 26, and the combined light enters the detection unit 32. The beam splitter 26 is a prism type beam splitter or a pellicle type beam splitter, as in the beam splitter 20.

The imaging optical system 28 and aperture stop 30 are inserted in the optical path between the beam splitter 26 and the detection unit 32. The lenses 28a and 28b form the bilateral telecentric imaging optical system 28 and image the surface of the substrate SB on the detection surface of the detection unit 32. Hence, in this embodiment, the transmission region in the slit plate 14 is imaged on the substrate SB and reference mirror 24 by the imaging optical system 16, and is imaged again on the detection surface of the detection unit 32 by the imaging optical system 28. Interference fringes (interference pattern) are formed on the detection surface of the detection unit 32 upon superposition (i.e., interference) between the measurement light and the reference light. Note that the aperture stop 30 located at the pupil position of the imaging optical system 28 defines the numerical aperture (NA) of the imaging optical system 28 and, in this embodiment, defines an NA as very low as about) sin(0.1°) to sin(5°).

A method of detecting (obtaining) an interference signal of interference fringes formed on the detection surface of the detection unit 32 will be explained herein. The substrate SB is supported by the stage system 22 including the substrate chuck 22a which holds the substrate SB, the Z stage 22b, the Y stage 22c, and the X stage 22d which align the substrate SB, as described above. To detect an interference signal of interference fringes between the measurement light and the reference light by the detection unit 32, the Z stage 22b need only be driven. To change the measurement region on the substrate SB, the substrate SB is aligned so that a desired region on the substrate SB is positioned in the detection region on the detection unit 32 using the Y stage 22c or X stage 22d. To control the positions of the Z stage 22b, Y stage 22c, and X stage 22d with high accuracy, laser interferometers need only be located on five axes, the X-, Y-, and Z-axes and the tilt axes ωy and ωy. The surface shape of the substrate SB can be measured with a higher accuracy by closed loop control of the stage positions based on the outputs from these laser interferometers. The use of laser interferometers is especially advantageous to obtain the entire surface shape of the substrate SB by dividing the substrate SB into a plurality of regions and measuring these divided regions because this allows more precise concatenation (stitching) of shape data.

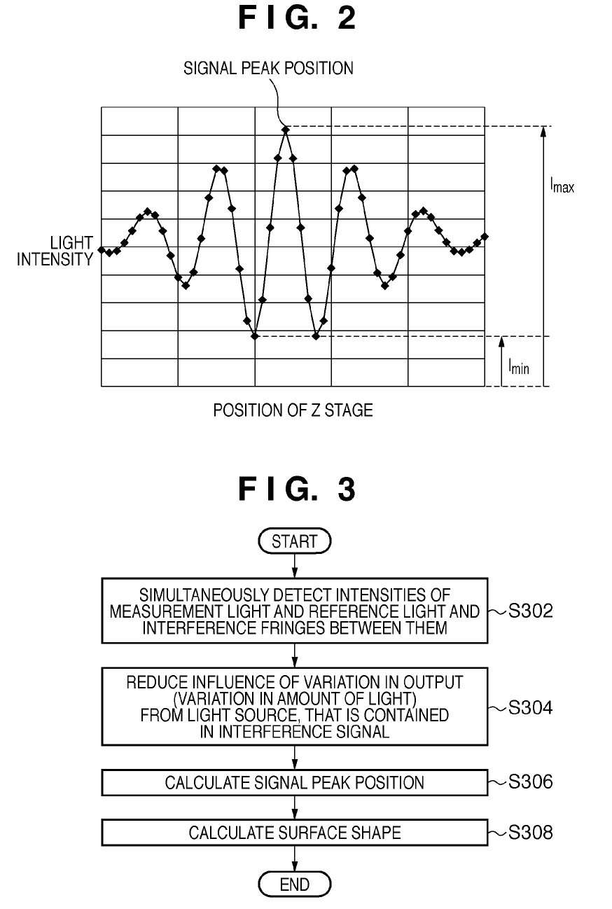

A process of calculating the surface shape of the substrate SB based on the interference signal of interference fringes detected (obtained) by the detection unit 32 will be explained next. The processing unit 34 performs this process and the surface shape of the substrate SB calculated by the processing unit 34 is, for example, stored in a storage unit (not shown) and displayed on a display unit (not shown). FIG. 2 is a graph illustrating an example of an interference signal (white light interference signal) detected by the detection unit 32. Note that FIG. 2 shows an interference signal detected using a two-dimensional image sensing device as the detection unit 32. The interference signal is also called an interferogram. In FIG. 2, the abscissa indicates the position of the Z stage 22b (more specifically, the measurement value obtained by a Z-axis length measurement interferometer or a capacitance sensor), and the ordinate indicates the output (light intensity) from the detection unit 32. The interference signal detected by the detection unit 32 is stored in the storage unit of the processing unit 34.

The position of the Z stage 22b (the measurement value obtained by the Z-axis length measurement interferometer) corresponding to a signal peak position calculated from the interference signal shown in FIG. 2 is the level of the substrate SB in the region where that measurement is performed (i.e., in a given pixel of the image sensing device). The three-dimensional shape of the substrate SB can be measured by obtaining the level of the substrate SB in each pixel of the two-dimensional image sensing device serving as the detection unit 32. To calculate the peak position of the interference signal, the interference signal need only be approximated by a curve (for example, a quadratic function) based on data of the signal peak position and several points before and after the signal peak position. With this operation, the signal peak position can be calculated at a resolution of about 1/10 to 1/50 a sampling pitch Zp on the abscissa (the position of the Z stage 22b) in FIG. 2. Note that the sampling pitch Zp is determined by the pitch at which the Z stage 22b is actually driven step by step at a constant pitch. However, when high speed is of prime importance in surface shape measurement of the substrate SB, the output from the Z-axis length measurement interferometer (the position of the Z stage 22b) is captured in synchronism with the detection timing of the detection unit 32 by driving the Z stage 22b at a constant speed.

To improve the calculation accuracy of the signal peak position, a peak intensity Imax of the interference signal shown in FIG. 2 is sufficiently higher than the intensity of electrical noise from the detection unit 32, and the contrast ((Imax−Imin)/(Imax+Imin)) is 0.75 or more. That the peak intensity Imax is sufficiently higher than the intensity of electrical noise means that the peak intensity Imax is 80% to 90% the maximum sensitivity of the detection unit 32. For this reason, it is necessary to adjust the light source 10 assuming 80% to 90% of the maximum sensitivity of the detection unit 32 as the light amount setting target (light control tolerance) so as to obtain an interference signal that satisfies the above-mentioned condition.

The FDA (Frequency Domain Analysis) method disclosed in U.S. Pat. No. 5,398,113 can also be used to calculate the signal peak position of the interference signal. The FDA method calculates the peak position of the contrast using the phase gradient of a Fourier spectrum.

In this manner, the resolution and accuracy of measurement which exploits the white light interference scheme depend on the accuracy of obtaining the position where the optical path length difference between the measurement light and the reference light is zero. Hence, the phase cross-correlation method or a method of obtaining the envelope of interference fringes by the phase shift method or the Fourier transform method and obtaining the position where the optical path length difference is zero from the maximum position of the contrast, for example, can also be used to calculate the signal peak position of the interference signal.

In the measurement apparatus 1, a fluctuation in output from the light source 10 (a variation in amount of light from the light source 10) turns into noise for the interference signal and therefore leads to deteriorations in surface shape measurement accuracy and reproducibility. To suppress deteriorations in measurement accuracy and reproducibility attributed to a fluctuation in output from the light source 10, the fluctuation in output from the light source 10 need only be detected and corrected. It is possible to detect a fluctuation in output from the light source 10 by, for example, splitting light from the light source 10 into light for use in surface shape measurement and that for use in output fluctuation detection. However, this method additionally requires an arrangement which detects light for use in output fluctuation detection. Furthermore, this method often cannot detect a fluctuation in output from the light source 10 with high accuracy due to the influence of, for example, a fluctuation of air and a temporal change and deterioration of an optical element which splits light from the light source 10 into light for use in surface shape measurement and that for use in output fluctuation detection. Still worse, since this method uses a certain component of light from the light source 10 as light for use in output fluctuation detection, the amount of light for use in surface shape measurement (i.e., the measurement light and reference light) is reduced.

To combat this situation, in this embodiment, the detection unit 32 detects the intensity of the measurement light reflected by the surface of the substrate SB, the intensity of the reference light reflected by the reference mirror 24, and interference fringes between the measurement light and the reference light. At this time, the intensity of the measurement light reflected by the surface of the substrate SB, the intensity of the reference light reflected by the reference mirror 24, and interference fringes between the measurement light and the reference light are detected simultaneously (in parallel). The processing unit 34 calculates the surface shape of the substrate SB while reducing the influence that a fluctuation in output from the light source 10 (a variation in amount of light from the light source 10) exerts on the interference signal of interference fringes between the measurement light and the reference light based on the intensities of the measurement light and reference light.

A measurement process in the measurement apparatus 1 will be explained below with reference to FIG. 3. This measurement process is a process of measuring the surface shape of the substrate SB, and is performed by systematically controlling each unit of the measurement apparatus 1 by the processing unit 34.

In step S302, the detection unit 32 simultaneously detects the intensity of the measurement light reflected by the surface of the substrate SB, the intensity of the reference light reflected by the reference mirror 24, and interference fringes between the measurement light and the reference light.

An oblique-incidence interferometer is generally adjusted so that the optical path length difference between measurement light and reference light is zero and the relative positional shift between the measurement light and the reference light is also zero in the optical path from a light source to a detection unit. This is because, when the optical path length difference between measurement light and reference light is zero and the relative positional shift between the measurement light and the reference light is also zero, an interference signal has a maximum contrast, thus contributing to a reduction in measurement errors and an improvement in reproducibility.

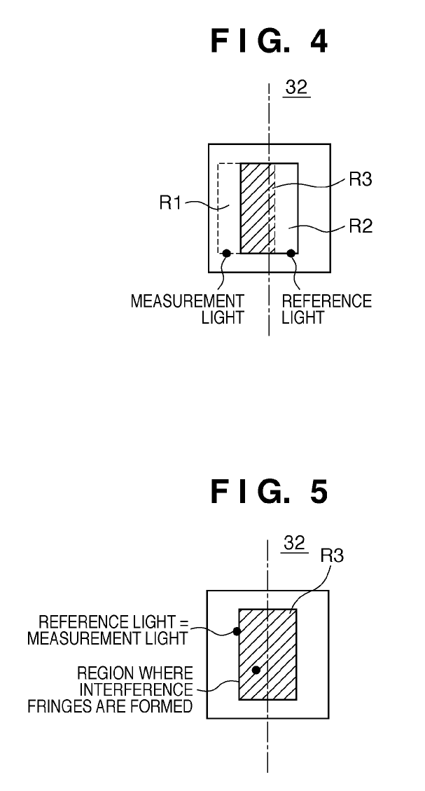

When high speed is of prime importance in surface shape measurement of the substrate SB in the measurement apparatus 1, the substrate SB is driven in only one direction along the Z-axis (i.e., the positive or negative Z-axis direction). In this case, an interference signal at the start of driving of the substrate SB corresponds to the leading edge of the overall interference signal, and the positional relationship between the measurement light and the reference light on the detection unit 32 (its detection surface) is as shown in FIG. 4. The peak of the interference signal is obtained as the substrate SB is driven, and the positional relationship between the measurement light and the reference light on the detection unit 32 (its detection surface) changes as shown in FIG. 5. Note that the positional relationship shown in FIG. 5 also serves as that between the measurement light and the reference light on the detection unit 32 (its detection surface) when the measurement apparatus 1 is adjusted so that the optical path length difference between the measurement light and the reference light is zero and the relative positional shift between the measurement light and the reference light is also zero.

The measurement light and the reference light on the detection unit 32 are shifted in position from each other at the start of driving of the substrate SB in one direction along the Z-axis, so not only a region R3 where the measurement light and the reference light are superposed on each other but also regions R1 and R2 where they are not superposed on each other are present at this time (see FIG. 4). In other words, at the start of driving of the substrate SB, the region R1 where only the measurement light enters, the region R2 where only the reference light enters, and the region R3 where both the measurement light and the reference light enter are present on the detection surface of the detection unit 32. Then, as the substrate SB is driven, a positional shift between the measurement light and the reference light disappears, and eventually, the region R3 where the measurement light and the reference light are superposed on each other (i.e., where both the measurement light and the reference light enter) alone is present (see FIG. 5).

Using this mechanism, in this embodiment, the processing unit 34 controls the position of the substrate SB so that the region R1 where only the measurement light enters, the region R2 where only the reference light enters, and the region R3 where both the measurement light and the reference light enter are present on the detection surface of the detection unit 32. With this operation, the detection unit 32 can simultaneously detect the intensities of the measurement light and reference light and interference fringes between the measurement light and the reference light. More specifically, the detection unit 32 detects the intensity of the measurement light in the region R1 where only the measurement light enters, detects the intensity of the reference light in the region R2 where only the reference light enters, and detects interference fringes in the region R3 where both the measurement light and the reference light enter.

The processing unit 34 may control the position of the reference mirror 24 so that the optical path length difference between the measurement light and the reference light is zero and a relative positional shift occurs between the measurement light and the reference light. Controlling the position of the reference mirror 24 in this way allows the region R1 where only the measurement light enters, the region R2 where only the reference light enters, and the region R3 where both the measurement light and the reference light enter to be present on the detection surface of the detection unit 32.

In this embodiment, one image sensing device constitutes the detection unit 32, which simultaneously detects the intensities of the measurement light and reference light and interference fringes between the measurement light and the reference light. However, the detection unit 32 need only be capable of simultaneously detecting the intensities of the measurement light and reference light and interference fringes between the measurement light and the reference light. For example, a light amount detection device (a measurement light detection unit) which detects the intensity of the measurement light, a light amount detection device (a reference light detection unit) which detects the intensity of the reference light, and an image sensing device (an interference light detection unit) which detects interference fringes between the measurement light and the reference light may constitute the detection unit 32.

In step S304, the influence of a fluctuation in output from the light source 10 (a variation in amount of light from the light source 10), that is contained in the interference signal of interference fringes detected in step S302, is reduced based on the intensities of the measurement light and reference light detected in step S302. In this embodiment, a signal in which the influence of a fluctuation in output from the light source 10, that is contained in the interference signal of interference fringes, is reduced is calculated as will be explained in detail below.

An interference signal I(Z) of interference fringes is given by:

$$I ( Z ) = {\sum }_{k} [ \frac{I ( k )}{2} ( Rr + Rm ) + 2 \frac{I ( k )}{2} \sqrt{RrRm} \times cos \{ 2 k cos ( {θ}_{in} ) Z + ( {ϕ}_{m} - {ϕ}_{r} ) \} ] \qquad ( 1 )$$

where k is the wave number (wavelength) of light from the light source 10, I(k) is the spectral intensity (the intensity for the wavelength), Rm is the intensity of measurement light, Rr is the intensity of reference light, θᵢₙ is the incident angle, Z is the position of the Z stage 22b, φₘ is the phase component of the measurement light, and φᵣ is the phase component of the reference light.

In equation (1), since variables which bear the information of a fluctuation in output from the light source 10 are the intensity Rm of the measurement light and the intensity Rr of the reference light, the intensity Rm of the measurement light and the intensity Rr of the reference light are eliminated from equation (1).

Subtracting terms associated with (Rr+Rm) from I(Z) in equation (1) yields a signal I′(Z):

$${I}^{′} ( Z ) = {\sum }_{k} [ 2 \frac{I ( k )}{2} \sqrt{RrRm} \times cos \{ 2 k cos ( {θ}_{in} ) Z + ( {ϕ}_{m} - {ϕ}_{r} ) \} ] \qquad ( 2 )$$

Dividing I′(Z) by √(RrRm) in equation (2) yields a signal I″(Z):

$${I}^{″} ( Z ) = {\sum }_{k} [ 2 \frac{I ( k )}{2} \times cos \{ 2 k cos ( {θ}_{in} ) Z + ( {ϕ}_{m} - {ϕ}_{r} ) \} ] \qquad ( 3 )$$

The signal I″(Z) given by equation (3) does not include the intensity Rm of the measurement light and the intensity Rr of the reference light. This means that the influence of a fluctuation in output from the light source 10 (a variation in amount of light from the light source 10) is reduced (eliminated) in the signal I″(Z).

In practice, a signal Ir″(Z) in which the influence of a fluctuation in output from the light source 10 (a variation in amount of light from the light source 10) is reduced need only be calculated in accordance with:

$${Ir}^{″} ( Z ) = \frac{Ir ( Z ) - ( R ( Z ) + M ( Z ) )}{\sqrt{R ( Z ) M ( Z )}} \qquad ( 4 )$$

In step S306, a signal peak position is calculated from the signal in which the influence of a fluctuation in output from the light source 10 is reduced (i.e., the signal Ir″(Z) calculated in step S304). Note that calculation of a signal peak position is the same as above, and a detailed description thereof will not be given herein.

In step S308, the surface shape of the substrate SB is calculated based on the signal peak position calculated in step S306. Note that calculation of the surface shape of the substrate SB is the same as above, and a detailed description thereof will not be given herein.

In this manner, in this embodiment, a signal peak position is calculated from a signal in which the influence of a fluctuation in output from the light source 10 is reduced, and the surface shape of the substrate SB is calculated from the signal peak position. Hence, the measurement apparatus 1 can measure the surface shape of a measurement target surface with high accuracy and good reproducibility by reducing the influence of a variation in amount of light from the light source 10 on the measurement result.

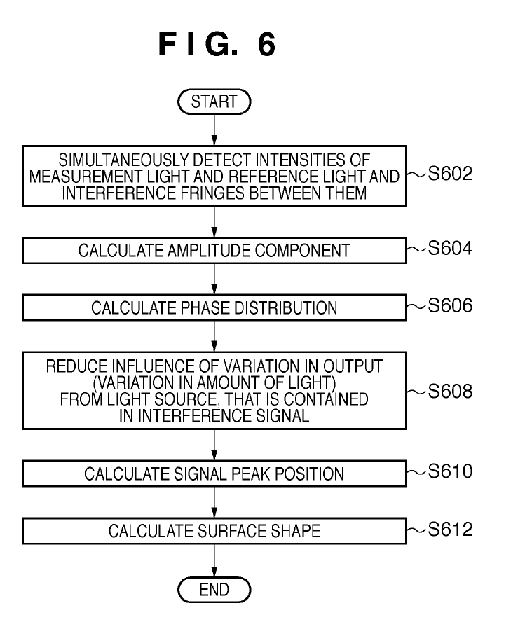

A signal in which the influence of a fluctuation in output from the light source 10 (a variation in amount of light from the light source 10) is reduced can also be calculated by Fourier-transforming the interference signal of an interference pattern detected by the detection unit 32, as shown in FIG. 6. FIG. 6 is a flowchart for explaining another measurement process in the measurement apparatus 1.

In step S602, the detection unit 32 simultaneously detects the intensity of the measurement light reflected by the surface of the substrate SB, the intensity of the reference light reflected by the reference mirror 24, and interference fringes between the measurement light and the reference light.

In step S604, the interference signal of interference fringes detected in step S602 is Fourier-transformed to calculate an amplitude component, that is, the spectral intensity attributed to the light source 10 and other optical members. When a reference plate, for example, is used as the measurement target surface, the spectral intensity attributed to the light source 10 and other optical members may be obtained in advance by, for example, a spectroscope.

In step S606, the interference signal of interference fringes detected in step S602 is Fourier-transformed to calculate a phase distribution.

In step S608, the influence of a fluctuation in output from the light source 10 (a variation in amount of light from the light source 10), that is contained in the interference signal of interference fringes detected in step S602, is reduced. In this embodiment, a signal in which the influence of a fluctuation in output from the light source 10 is reduced is calculated based on the intensities of the measurement light and reference light detected in step S602, the amplitude component calculated in step S604, and the phase distribution calculated in step S606.

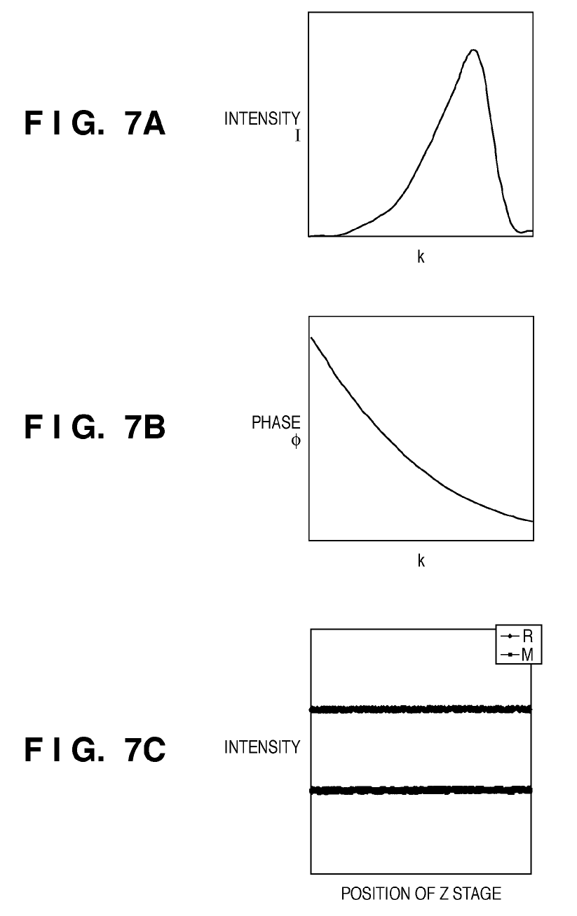

FIGS. 7A to 7C are graphs for explaining calculation of a signal in which the influence of a fluctuation in output from the light source 10 is reduced in step S608. FIG. 7A is a graph showing the amplitude component (spectral intensity) calculated in step S604; in which the abscissa indicates the wave number k of light from the light source 10, and the ordinate indicates the intensity I. FIG. 7B is a graph showing the phase distribution calculated in step S606; in which the abscissa indicates the wave number k of light from the light source 10, and the ordinate indicates the phase φ. FIG. 7C is a graph showing the intensity M of the measurement light and the intensity R of the reference light, both of which are detected at each position to which the substrate SB is driven in the Z-axis direction; in which the abscissa indicates the position of the Z stage 22b, and the ordinate indicates the intensity.

In step S608, a signal in which the influence of a fluctuation in output from the light source 10 is reduced is calculated using equation (1) based on various types of information shown in FIGS. 7A to 7C. More specifically, in equation (1), the amplitude component shown in FIG. 7A is substituted for I(k), the phase component shown in FIG. 7B is substituted for (φₘ-φᵣ), the intensity M of the measurement light shown in FIG. 7C is substituted for Rm, and the intensity R of the reference light shown in FIG. 7C is substituted for Rr. A signal in which the influence of a fluctuation in output from the light source 10 is calculated when the average values in all regions across which the substrate SB is driven in the Z-axis direction are used for the intensity M of the measurement light and the intensity R of the reference light. Alternatively, the signal may be calculated by obtaining a fluctuation in intensity of the interference signal using the intensity M of the measurement light and the intensity R of the reference light at each position on the substrate SB in the Z-axis direction and eliminating the fluctuation from the interference signal.

In step S610, a signal peak position is calculated from the signal in which the influence of a fluctuation in output from the light source 10 is reduced (i.e., the signal calculated in step S608).

In step S612, the surface shape of the substrate SB is calculated based on the signal peak position calculated in step S610.

In this manner, a signal in which the influence of a fluctuation in output from the light source 10 is reduced can also be calculated by Fourier-transforming the interference signal of an interference pattern detected by the detection unit 32. This makes it possible to measure the surface shape of a measurement target surface with high accuracy and good reproducibility.

Note that, in the process of measuring the surface shape of the substrate SB, the amount of reference light detected by the detection unit 32 stays unchanged because the surface reflectance of the reference mirror 24 stays constant, but the amount of measurement light detected by the detection unit 32 changes because the surface reflectance of the substrate SB changes depending on its material. As a result, the light intensity and contrast of an interference signal obtained by interference between the measurement light and the reference light may decrease, and the surface shape measurement accuracy may, in turn, deteriorate due to factors including the influence of noise.

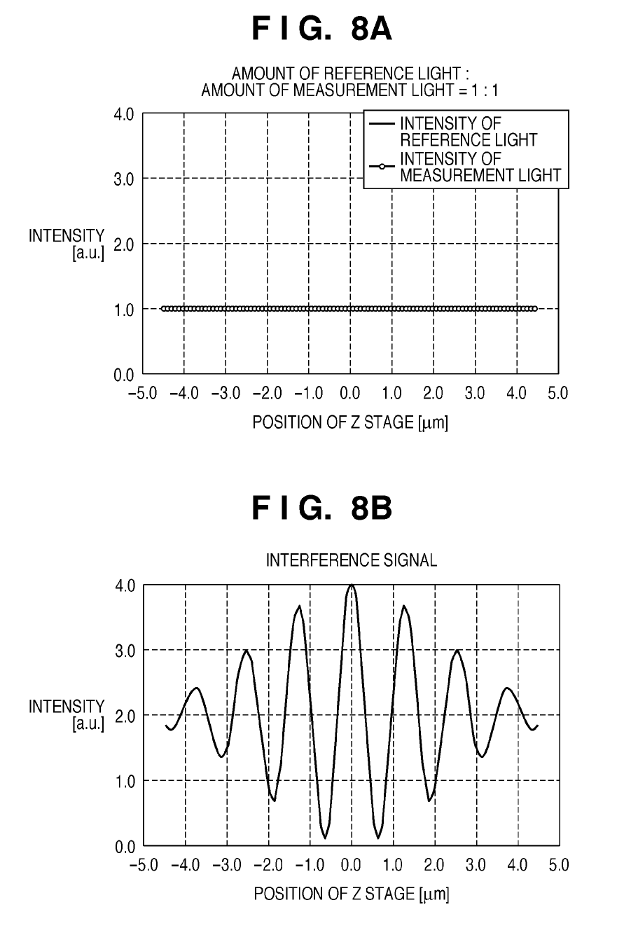

FIG. 8A shows the intensities of the measurement light and reference light detected by the detection unit 32 and FIG. 8B shows an interference signal of interference fringes detected by the detection unit 32, both when the reflectance of the substrate SB is equal to that of the reference mirror (Amount of Measurement Light: Amount of Reference Light on Detection Unit 32=1:1). At this time, the intensity peak of the interference signal shown in FIG. 8B is 1+1+2×√(1×1)=4.0.

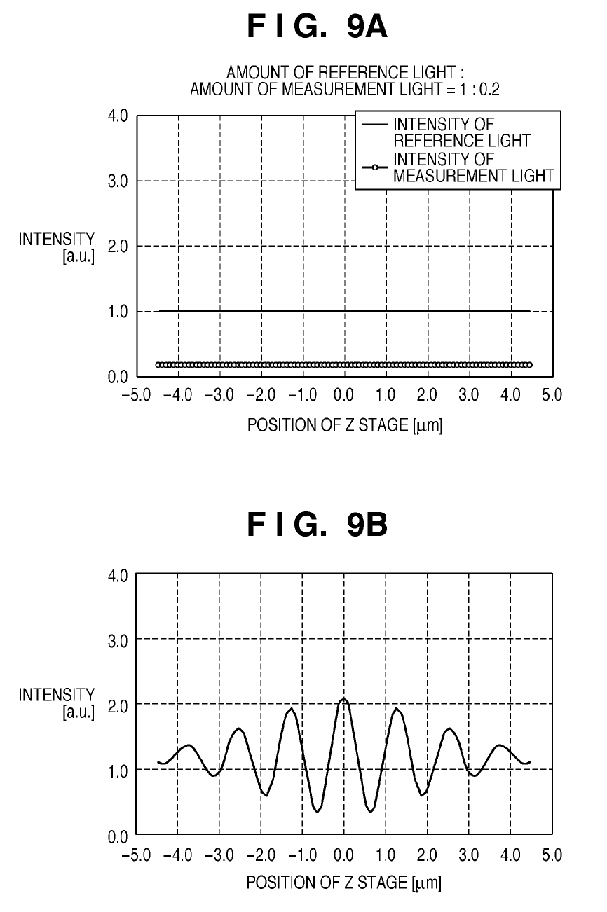

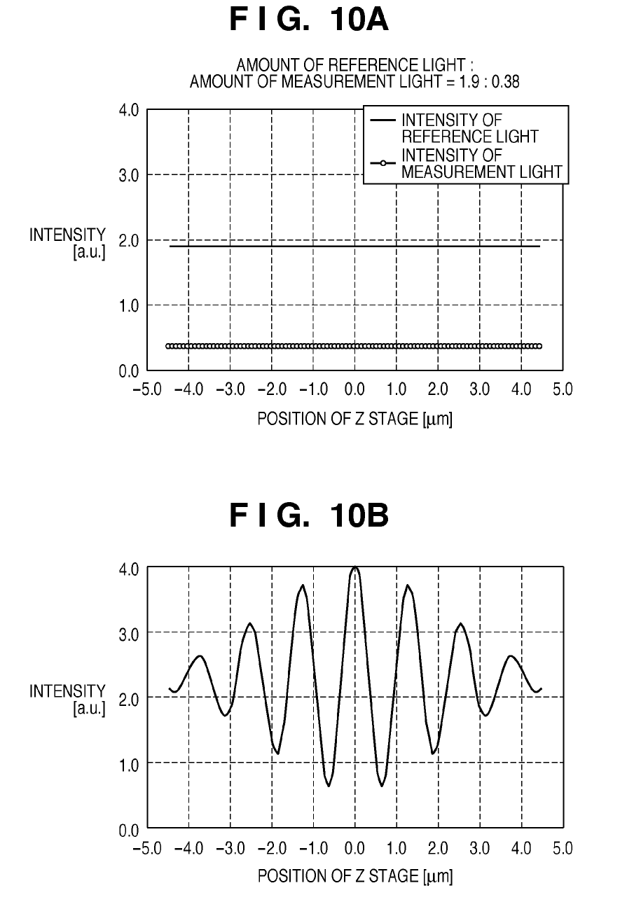

FIG. 9A shows the intensities of the measurement light and reference light detected by the detection unit 32 and FIG. 9B shows an interference signal of interference fringes detected by the detection unit 32, both when the reflectance of the substrate SB is lower than that of the reference mirror (Amount of Measurement Light: Amount of Reference Light on Detection Unit 32=0.2:1). At this time, the intensity peak of the interference signal shown in FIG. 9B is 1+0.2+2×√(1×0.2)≈2.1. Let A be the amount of light from the light source 10. In this manner, when the intensity peak or contrast of the interference signal is low, the surface shape measurement accuracy deteriorates due to the influence of a fluctuation of air and noise attributed to the detection unit 32. It is possible to prevent deterioration in measurement accuracy by boosting the electrical output gain of the detection unit 32, but this is undesirable because electrical noise attributed to the detection unit 32 increases at the same time. To combat this situation, in this embodiment, the amount of light from the light source 10 is adjusted based on the intensity ratio between the measurement light and the reference light on the detection unit 32. More specifically, the light source 10 is adjusted so that the amount of light from the light source 10 becomes A×4.0/2.1(=A×1.9). With this operation, the intensities of the measurement light and reference light detected by the detection unit 32 change as shown in FIG. 10A, and the interference signal of interference fringes detected by the detection unit 32 changes as shown in FIG. 10B. This makes it possible to improve the intensity peak and contrast of the interference signal.

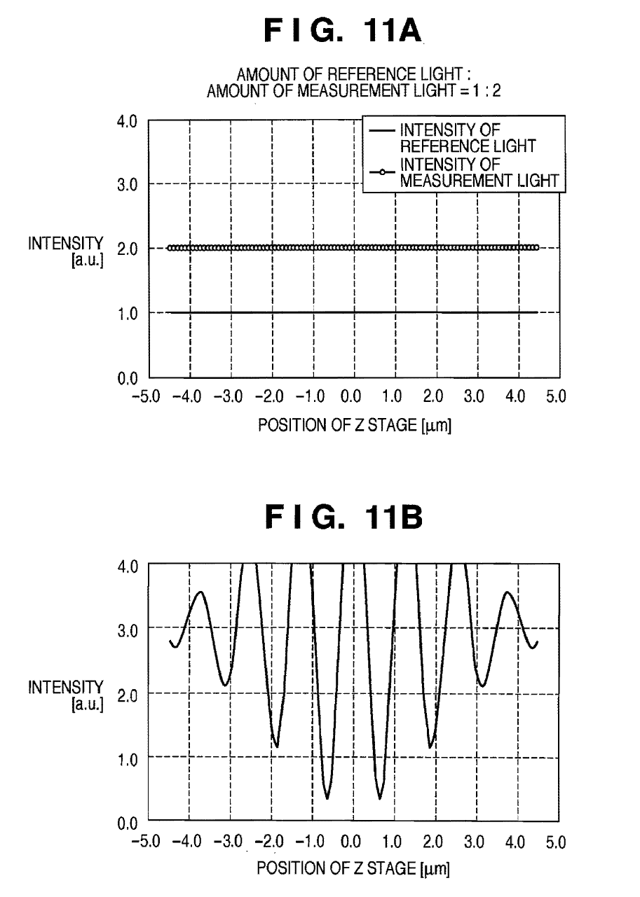

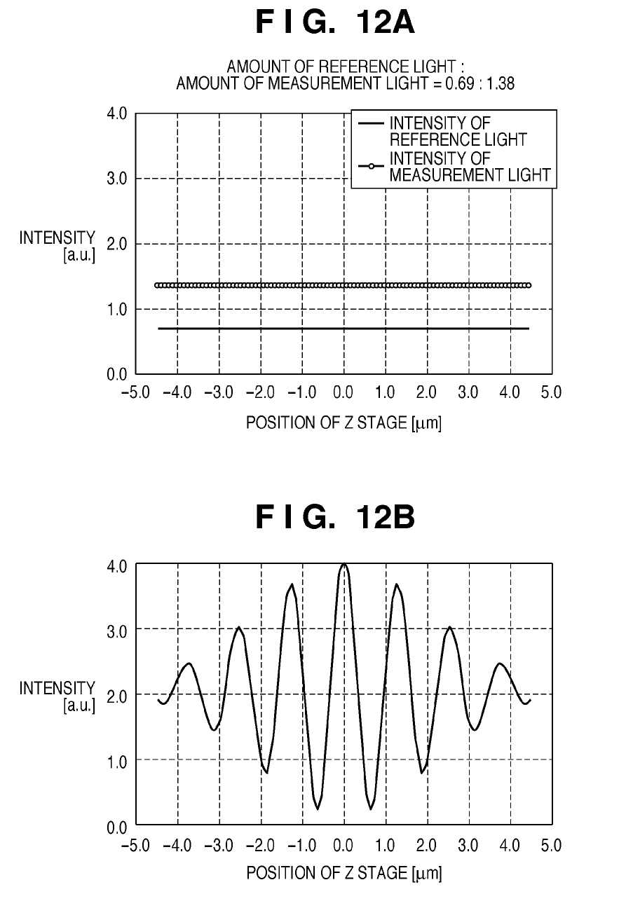

In contrast, FIG. 11A shows the intensities of the measurement light and reference light detected by the detection unit 32 and FIG. 11B shows an interference signal of interference fringes detected by the detection unit 32, both when the reflectance of the substrate SB is higher than that of the reference mirror 24 (Amount of Measurement Light: Amount of Reference Light on Detection Unit 32=2:1). At this time, the intensity peak of the interference signal shown in FIG. 11B is 1+2+2×√(1×2)≈5.8, and this means that the intensity peak of the interference signal exceeds the output limit of the detection unit 32 (that peak reaches a saturation). Let A be the amount of light from the light source 10. In this manner, when the intensity peak or contrast of the interference signal exceeds the output limit of the detection unit 32, it is very difficult to adjust (optimize) the light source 10. To overcome this difficulty, in this embodiment, the amount of light from the light source 10 is adjusted based on the intensity ratio between the measurement light and the reference light on the detection unit 32. More specifically, the light source 10 is adjusted so that the amount of light from the light source 10 becomes A×4.0/5.8 (=A×0.69). With this operation, the intensities of the measurement light and reference light detected by the detection unit 32 change as shown in FIG. 12A, and the interference signal of interference fringes detected by the detection unit 32 changes as shown in FIG. 12B.

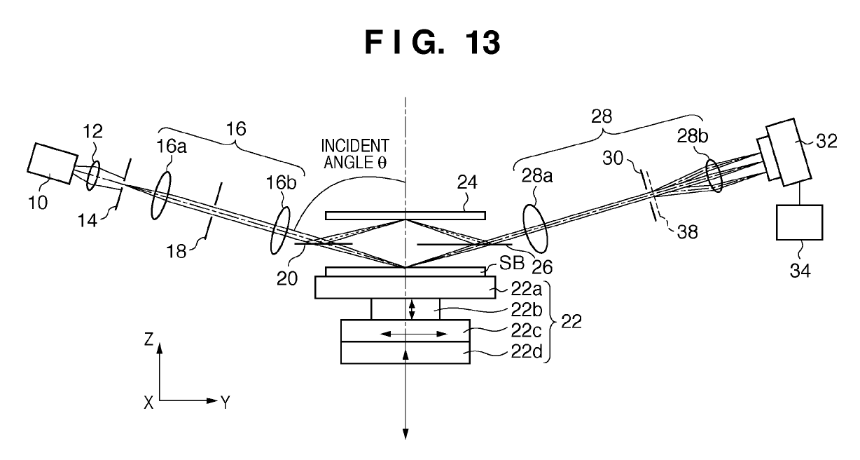

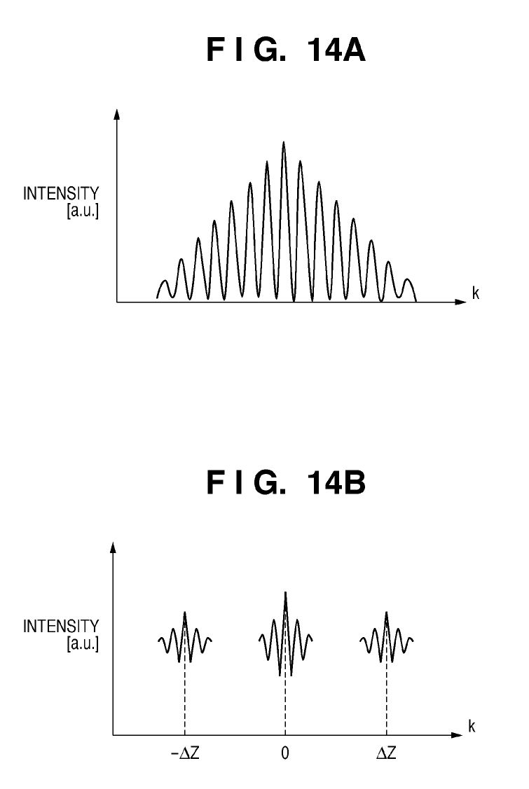

Also, in this embodiment, the detection unit 32 simultaneously detects the intensities of the measurement light and reference light and interference fringes between the measurement light and the reference light by controlling the position of the substrate SB or reference mirror 24. However, as shown in FIG. 13, an optical element (for example, a prism or a diffraction grating) 38 which splits (disperses) combined light of the measurement light reflected by the substrate SB and the reference light reflected by the reference mirror 24 may be inserted between the substrate SB and reference mirror 24 and the detection unit 32. In this case, the detection unit 32 detects an interference signal as shown in FIG. 14A. The interference signal shown in FIG. 14A depends on the optical path length difference (ΔZ) between the measurement light and the reference light, and the wave number (k=2π/λ (where λ is the wavelength of light from the light source 10) of light from the light source 10. Hence, Fourier transformation of the interference signal shown in FIG. 14A can yield an interference signal which depends on the optical path length difference (ΔZ), as in a case in which the substrate SB is driven, as shown in FIG. 14B. U.S. Pre-Grant Publication No. 2007/0086013, for example, discloses details of this technique.

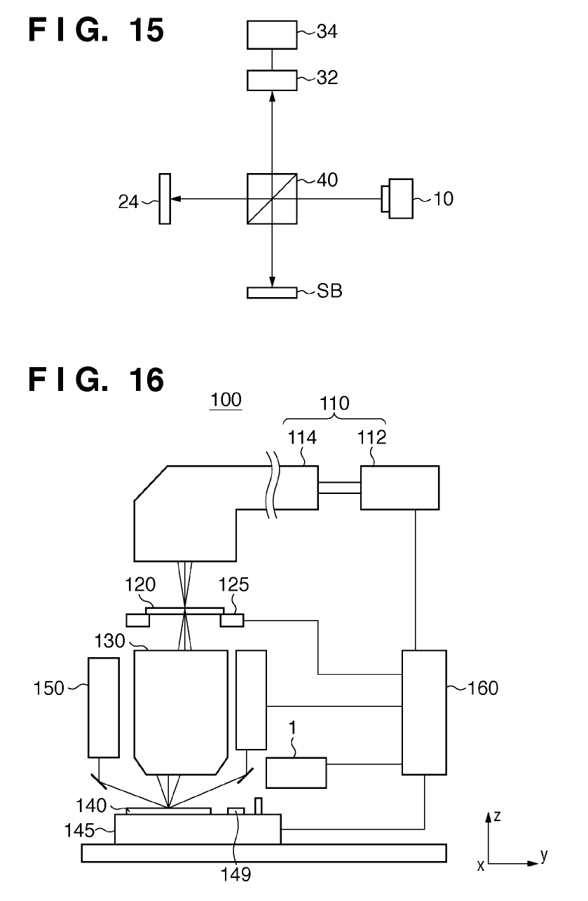

Moreover, although the measurement apparatus 1 is an oblique-incidence interferometer, it may be a normal-incidence interferometer, as shown in FIG. 15. In this case, the region R1 where only the measurement light enters, the region R2 where only the reference light enters, and the region R3 where both the measurement light and the reference light enter need to be set on the detection surface of the detection unit 32 in advance, as shown in FIG. 4. This setting can be done by, for example, tilting the reference mirror 24 or coating the surface of an optical member, located in the subsequent stage of a half mirror 40 for splitting light from the light source 10 into measurement light and reference light, with, for example, a light-shielding film.

Further, although this embodiment describes a construction whereby the light intensity of both the measurement light and the reference light are detected, it suffices to detect only one of the light intensity of the measurement light and the light intensity of the reference light. For example, when the reflectance of the measurement target surface is equal to the reflectance of the reference surface, if either the light intensity of the measurement light or of the reference light is detected, the light intensity of the other side can be known. Furthermore, when the reflectance of the measurement target surface is different from that of the reference surface, by obtaining each reflectance of both the measurement target surface and the reference surface in advance, the light intensity of one side can be known form the detected light intensity of the other side.

Therefore, it suffices to include at least one of a measurement light detection unit and reference light detection unit which detect light intensity; similarly, it suffices to include at least one of the region where the measurement light enters and the region where the reference light enters.

An exposure apparatus 100 including a measurement apparatus 1 will be explained next with reference to FIG. 16. FIG. 16 is a schematic view showing the arrangement of the exposure apparatus 100 according to one aspect of the present invention.

In this embodiment, the exposure apparatus 100 is a projection exposure apparatus which transfers the pattern of a reticle 120 onto a wafer 140 by exposure of the step & scan scheme. However, the exposure apparatus 100 can also adopt the step & repeat scheme or another exposure scheme.

As shown in FIG. 16, the exposure apparatus 100 includes an illumination apparatus 110, a reticle stage 125 which mounts the reticle 120, a projection optical system 130, a wafer stage 145 which mounts the wafer 140, a focus control sensor 150, and a control unit 160.

The illumination apparatus 110 illuminates the reticle 120 on which a pattern to be transferred is formed, and includes a light source 112 and illumination optical system 114.

The light source 112 is, for example, an ArF excimer laser having a wavelength of about 193 nm or a KrF excimer laser having a wavelength of about 248 nm. However, the light source 112 is not limited to an excimer laser, and may be, for example, an F₂ laser having a wavelength of about 157 nm.

The illumination optical system 114 illuminates the reticle 120 with light from the light source 112. In this embodiment, the illumination optical system 114 forms an exposure slit having a shape optimum for exposure. The illumination optical system 114 includes, for example, a lens, mirror, optical integrator, and stop.

The reticle 120 has a pattern to be transferred and is supported and driven by the reticle stage 125. Diffracted light generated by the reticle 120 is projected onto the wafer 140 upon passing through the projection optical system 130. The reticle 120 and the wafer 140 are placed optically conjugate to each other. The exposure apparatus 100 includes a reticle detection unit of the light oblique-incidence system (not shown). The reticle 120 has its position detected by the reticle detection unit and is located at a predetermined position.

The reticle stage 125 supports the reticle 120 through a reticle chuck (not shown) and is connected to a moving mechanism (not shown). The moving mechanism includes, for example, a linear motor and drives the reticle stage 125 in the X-, Y-, and Z-axis directions and the rotation directions about the respective axes.

The projection optical system 130 projects the pattern of the reticle 120 onto the wafer 140. The projection optical system 130 can be a dioptric system, a catadioptric system, or a catoptric system.

The wafer 140 is a substrate onto which the pattern of the reticle 120 is projected (transferred), and is supported and driven by the wafer stage 145. However, a glass plate or another substrate can also be used in place of the wafer 140. The wafer 140 is coated with a resist.

The wafer stage 145 supports the wafer 140 through a wafer chuck (not shown). The wafer stage 145 moves the wafer 140 in the X-, Y-, and Z-axis directions and the rotation directions about the respective axes using a linear motor, as in the reticle stage 125. A reference plate 149 is also located on the wafer stage 145.

The focus control sensor 150 has a function of measuring the surface shape of the wafer 140, as in the measurement apparatus 1. The focus control sensor 150 exhibits a good response characteristic but is prone to generate an error attributed to the wafer pattern.

The measurement apparatus 1 can take any of the above-mentioned forms, and a detailed description thereof will not be given. The measurement apparatus 1 has a poor response characteristic but is less prone to generate an error attributed to the wafer pattern.

The control unit 160 includes a CPU and memory and controls the operation of the exposure apparatus 100. In this embodiment, the control unit 160 serves as a processing unit of the focus control sensor 150. Hence, the control unit 160 performs correction calculation and control of the measurement value obtained by measuring the surface shape of the wafer 140 by the focus control sensor 150. The control unit 160 may also function as the processing unit 34 of the measurement apparatus 1.

Points at which the surface shapes (focuses) of the wafer 140 are measured will be explained herein. In this embodiment, the surface shape of the wafer 140 is measured by the focus control sensor 150 while scanning the wafer stage 145 in the scanning direction (Y-axis direction) over the entire surface of the wafer 140. The profile of the entire surface of the wafer 140 is obtained by repeating an operation of moving the wafer stage 145 step by step by ΔX in a direction (X-axis direction) perpendicular to the scanning direction and measuring the surface shape of the wafer 140 in the scanning direction. The surface shapes of the wafer 140 in different regions on the wafer 140 may be simultaneously measured using a plurality of focus control sensors 150. This makes it possible to improve the throughput.

In this embodiment, the focus control sensor 150 is an optical level measurement system. More specifically, the focus control sensor 150 guides light to enter the surface of the wafer 140 at a small incident angle and detects, by, for example, a CCD, an image shift of the light reflected by the surface of the wafer 140. The focus control sensor 150 guides light beams to a plurality of measurement points on the wafer 140, separately receives the light beams reflected at these measurement points, and calculates the tilt of the surface to be exposed based on the pieces of level information at different positions.

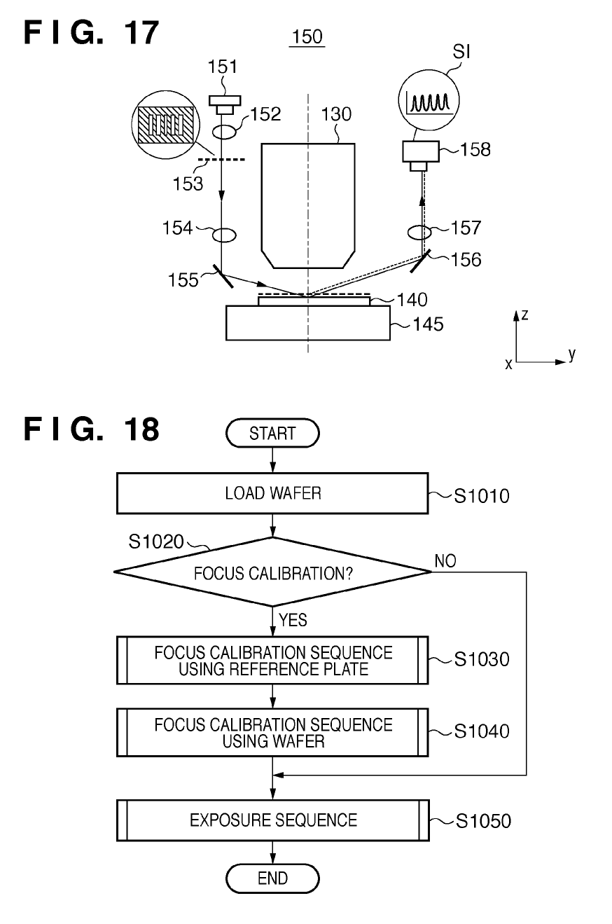

The focus control sensor 150 will be explained in detail with reference to FIG. 17. FIG. 17 is a schematic view showing the arrangement of the focus control sensor 150. As shown in FIG. 17, the focus control sensor 150 includes a light source 151, a condenser lens 152, a pattern plate 153 having a plurality of transmission slits formed in it, a lens 154, and a mirror 155. The focus control sensor 150 also includes a mirror 156, a lens 157, and a light-receiving device 158 such as a CCD.

Light from the light source 151 is converged via the condenser lens 152 and illuminates the pattern plate 153. The light having passed through the transmission slits in the pattern plate 153 enters the wafer 140 at a predetermined angle via the lens 154 and mirror 155. Because the pattern plate 153 and the wafer 140 are placed in an imaging relationship via the lens 154, aerial images of the transmission slits in the pattern plate 153 are formed on the wafer 140.

The light reflected by the wafer 140 is received by the light-receiving device 158 via the mirror 156 and lens 157 to obtain a signal SI which bears the information of a slit image corresponding to each transmission slit in the pattern plate 153, as shown in FIG. 17. The position of the wafer 140 in the Z-axis direction can be measured by detecting a positional shift of the signal SI on the light-receiving device 158. An amount of optical axis shift m1 on the wafer 140 when the surface of the wafer 140 changes from a position w1 to a position w2 in the Z-axis direction is given by m1=2·dZ·tan θᵢₙ, where θᵢₙ is the incident angle, and dZ is the amount of change from the position w1 to the position w2.

When, for example, the incident angle θᵢₙ is 84°, m1=19·dZ, that is equal to an amount of displacement 19 times that of displacement of the wafer 140. The amount of displacement on the light-receiving device 158 is obtained by multiplying m1 by the magnification of the optical system (the imaging magnification of the lens 157).

The exposure operation of the exposure apparatus 100 (an exposure method using the exposure apparatus 100) will be explained below. FIG. 18 is a flowchart for explaining the exposure operation of the exposure apparatus 100.

First, in step S1010, a wafer 140 is loaded into the exposure apparatus 100.

In step S1020, it is checked whether to perform focus calibration of the focus control sensor 150 for the wafer 140 loaded in step S1010. More specifically, this determination is done based on pieces of information, registered in the exposure apparatus 100 in advance by the user, such as “whether the loaded wafer is the first wafer in a lot”, “whether the loaded wafer is the first wafer in a plurality of lots”, and “whether the loaded wafer is a wafer in a process which requires strict focus accuracy”.

If it is determined in step S1020 that focus calibration of the focus control sensor 150 is not to be performed, the process advances to step S1050, in which an exposure sequence (to be described later) is performed.

If it is determined in step S1020 that focus calibration of the focus control sensor 150 is to be performed, the process advances to step S1030, in which a focus calibration sequence using the reference plate 149 is performed.

Subsequently, in step S1040, a focus calibration sequence using the wafer 140 is performed.

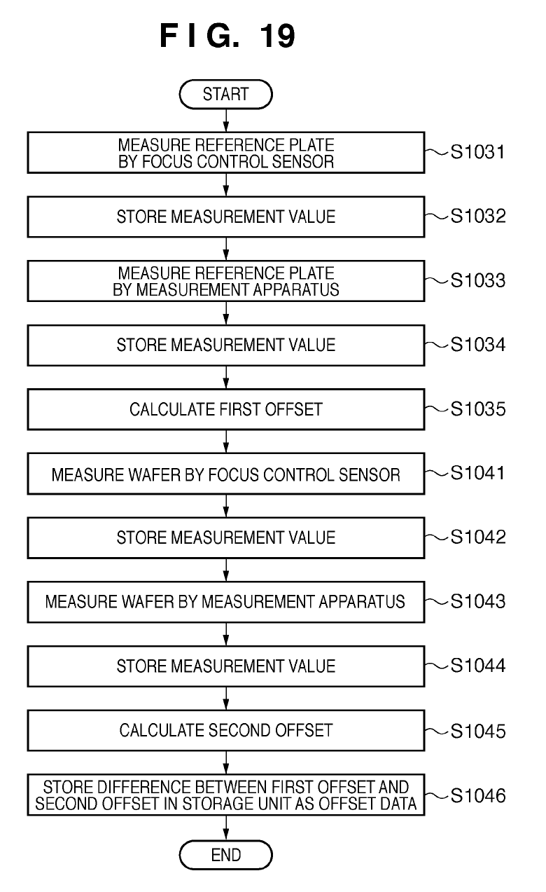

The focus calibration sequences in steps S1030 and S1040 will be explained herein with reference to FIG. 19. FIG. 19 is a detailed flowchart of the focus calibration sequences in steps S1030 and S1040.

In the focus calibration sequence using the reference plate 149, the reference plate 149 is positioned at a position below the focus control sensor 150 by driving the wafer stage 145 first. Note that the reference plate 149 is made of a glass plate, with a high surface accuracy, called an optical flat. Note also that a uniform region free from any reflectance distribution is set on the surface of the reference plate 149 so as to prevent the focus control sensor 150 from generating measurement errors, and the focus control sensor 150 measures the uniform region. However, a part of a plate on which various types of calibration marks necessary for other types of calibration of the exposure apparatus 100 are formed may be used as the reference plate 149.

In step S1031, the position of the reference plate 149 in the Z-axis direction is measured by the focus control sensor 150.

In step S1032, the position of the reference plate 149 in the Z-axis direction (a measurement value Om) measured in step S1031 is stored in a storage unit (for example, the memory of the control unit 160) of the exposure apparatus 100.

The reference plate 149 is positioned at a position below the measurement apparatus 1 by driving the wafer stage 145 next.

In step S1033, the surface shape of the reference plate 149 is measured by the measurement apparatus 1. Note that the measurement region (X-Y plane) on the reference plate 149 measured by the measurement apparatus 1 is the same as that measured by the focus control sensor 150 in step S1031.

In step S1034, the surface shape of the reference plate 149 (a measurement value Pm) measured in step S1033 is stored in the storage unit.

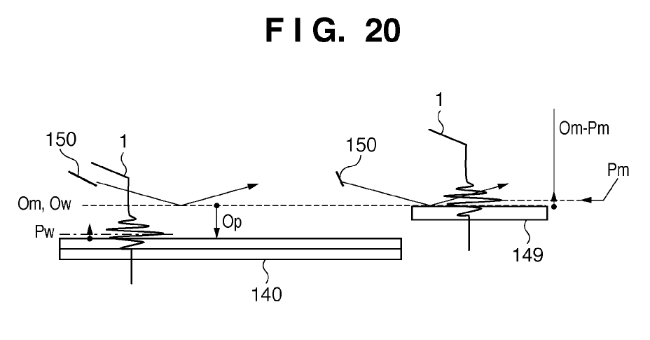

In step S1035, a first offset is calculated. More specifically, a first offset is calculated as the difference between the measurement value Pm obtained by the measurement apparatus 1 and the measurement value Om obtained by the focus control sensor 150, as shown in FIG. 20. The first offset is theoretically expected to be zero because it is obtained by measuring the optically uniform surface of the reference plate 149 and so the focus control sensor 150 generates no measurement errors. However, the first offset is not zero in practice due to error factors such as a systematic offset of the wafer stage 145 in the scanning direction, and a long-term drift of the focus control sensor 150 or measurement apparatus 1. Hence, first offsets are periodically obtained (calculated). Nevertheless, a first offset need only be obtained once when the above-mentioned error factors are guaranteed not to occur or are separately controlled. FIG. 20 is a view for explaining a first offset and a second offset (to be described later) in the focus calibration sequences.

Steps S1031 to S1035 correspond to the focus calibration sequence using the reference plate 149.

In the focus calibration sequence using the wafer 140, the wafer 140 is positioned at a position below the focus control sensor 150 by driving the wafer stage 145 first. Note that a measurement position Wp on the wafer 140 (within the wafer plane) is the same as the measurement position in an exposure sequence (to be described later).

In step S1041, the position of the measurement position Wp in the Z direction on the wafer 140 is measured by the focus control sensor 150.

In step S1042, the position of the measurement position Wp on the wafer 140 (a measurement value Ow) measured in step S1041 is stored in the storage unit.

The measurement position Wp on the wafer 140 is positioned at a position below the measurement apparatus 1 by driving the wafer stage 145 next.

In step S1043, the surface shape of the wafer 140 at the measurement position Wp on the wafer 140 is measured by the measurement apparatus 1.

In step S1044, the surface shape of the wafer 140 at the measurement position Wp on the wafer 140 (a measurement value Pw) measured in step S1043 is stored in the storage unit. Note that the measurement position Wp serving as a measurement point on the wafer 140 can be selected from various types of modes such as one point within the plane of a wafer, one point within a shot, all points within a shot, all points within a plurality of shots, and all points within the plane of a wafer.

In step S1045, a second offset is calculated. More specifically, a second offset is calculated for each measurement position Wp on the wafer 140 as the difference between the measurement value Pw obtained by the measurement apparatus 1 and the measurement value Ow obtained by the focus control sensor 150, as shown in FIG. 20.

In step S1046, the difference between the first offset and the second offset is obtained for each measurement position Wp on the wafer 140, and the obtained differences are stored in the storage unit as offset data. An offset amount Op at each measurement position on the wafer 140 can be calculated by Op(i)=[Ow(i)−Pw(i)]−(Om−Pm) where i is the point number indicating the measurement position on the wafer 140.

An average level offset (Z) or an average tilt offset (ωz and ωy) may be stored for each exposure shot (for each shot in case of a stepper or for each exposure slit in case of a scanner) as the offset amount Op. Since the pattern transferred onto the wafer 140 is repeated in shots (dice), the offset amount Op may be calculated as the average among respective shots on the wafer 140.

Steps S1041 to S1046 correspond to the focus calibration sequence using the wafer 140.

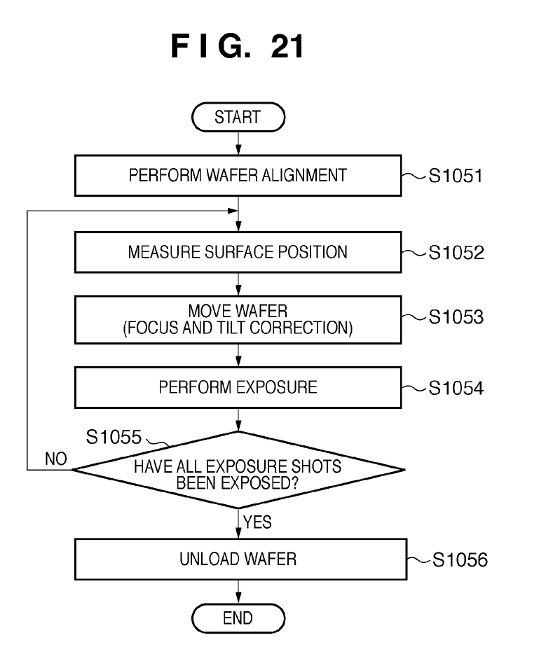

An exposure sequence in step S1050 after completion of the focus calibration sequences in steps S1030 and S1040 will be explained next with reference to FIG. 21. FIG. 21 is a detailed flowchart of the exposure sequence in step S1050.

In step S1051, wafer alignment is performed. In the wafer alignment, the position of an alignment mark on the wafer 140 is detected by an alignment scope (not shown), and the X-Y plane of the wafer 140 is aligned with that of the exposure apparatus 100.

In step S1052, the surface position of the wafer 140 in a predetermined region on the wafer 140 is measured by the focus control sensor 150. The predetermined region includes the region on the wafer 140, which is measured in the above-mentioned focus calibration sequences. Hence, the surface shape of the wafer 140 over its entire surface is measured by correcting the measurement values by offset amounts Op(i). The thus corrected surface shape data of the wafer 140 is stored in the storage unit of the exposure apparatus 100.

In step S1053, the wafer 140 is moved so that the first exposure shot shifts from the measurement position below the focus control sensor 150 to the exposure position below the projection optical system 130 by driving the wafer stage 145. At this time, surface shape data of the first exposure shot is generated based on the surface shape data of the wafer 140, and the focus (Z direction) and the tilt (tilt directions) are corrected so that the amount of shift of the surface of the wafer 140 with respect to the exposure image plane becomes minimum. In this way, the surface of the wafer 140 is aligned with the position of an optimum exposure image plane for each exposure slit.

In step S1054, the pattern of the reticle 120 is transferred onto the wafer 140 by exposure. At this time, since the exposure apparatus 100 is a scanner, it transfers the pattern of the reticle 120 onto the wafer 140 by scanning them in the Y direction (scanning direction).

In step S1055, it is checked whether all exposure shots have been exposed. If it is determined that not all exposure shot have been exposed yet, the process returns to step S1052. In step S1052, surface shape data of the next exposure shot is generated, and the focus and tilt are corrected, thereby performing exposure while aligning the surface of the wafer 140 with an optimum exposure image plane for each exposure slit. In contrast, if it is determined that all exposure shots have been exposed, the wafer 140 is unloaded from the exposure apparatus 100 in step S1056.

In this embodiment, the generation of surface shape data of an exposure shot, the calculation of the amount of shift from the exposure image plane, and the calculation of the amount of driving of the wafer stage 145 are performed immediately before each exposure shot is exposed. However, the generation of surface shape data, the calculation of the amount of shift from the exposure image plane, and the calculation of the amount of driving of the wafer stage 145 may be performed for all exposure shots before the first exposure shot is exposed.

Also, the wafer stage 145 is not limited to a single-stage configuration, and may have a so-called twin-stage configuration including two stages, an exposure stage for use in exposure and a measurement stage for use in alignment and surface shape measurement of the wafer 140. In this case, the focus control sensor 150 and measurement apparatus 1 are located on the side of the measurement stage.

The measurement apparatus 1 in the exposure apparatus 100 can measure the wafer surface shape with high accuracy and good reproducibility, as described above. This makes it possible to improve the focus accuracy between the exposure plane and the wafer surface, leading to improvements in device performance and fabrication yield. Hence, the exposure apparatus 100 can provide high-quality devices (for example, a semiconductor device, an LCD device, an image sensing device (for example, a CCD), and a thin-film magnetic head) with a high throughput and good economical efficiency. These devices are fabricated by a step of exposing a substrate (for example, a wafer or a glass plate) coated with a photosensitive agent using the exposure apparatus 100, a step of developing the exposed substrate (photosensitive agent), and other known steps.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2009-031963 filed on Feb. 13, 2009, which is hereby incorporated by reference herein in its entirety.

What is claimed is:

1. A measurement apparatus which measures a surface shape of a measurement target surface, the apparatus comprising:
an optical system configured to split light from a light source into measurement light and reference light, guide the measurement light onto the measurement target surface, and guide the reference light onto a reference surface;
a detection unit configured to detect an intensity of the measurement light reflected by the measurement target surface, an intensity of the reference light reflected by the reference surface, and an interference pattern formed between the measurement light reflected by the measurement target surface and the reference light reflected by the reference surface; and
a processing unit configured to obtain a surface shape of the measurement target surface based on an interference signal of the interference pattern detected by said detection unit,
wherein said processing unit obtains the surface shape of the measurement target surface based on at least one of the intensities of the measurement light and the reference light detected by said detection unit and the interference signal of the interference pattern detected by said detection unit.

2. The apparatus according to claim 1, wherein
said processing unit controls a position of one of the measurement target surface and the reference surface so that a region where only the measurement light enters, a region where only the reference light enters, and a region where both the measurement light and the reference light enter are present on said detection unit, and
said detection unit detects the intensity of the measurement light in the region where only the measurement light enters, detects the intensity of the reference light in the region where only the reference light enters, and detects the interference pattern in the region where both the measurement light and the reference light enter.

3. The apparatus according to claim 1, wherein
said detection unit includes
an interference light detection unit configured to detect the interference signal of the interference pattern,
a measurement light detection unit configured to detect the intensity of the measurement light reflected by the measurement target surface, and
a reference light detection unit configured to detect the intensity of the reference light reflected by the reference surface.

4. The apparatus according to claim 1, wherein
said processing unit obtains the surface shape of the measurement target surface while reducing an influence of a variation in amount of light from the light source, that is contained in the interference signal of the interference pattern detected by said detection unit, based on the intensities of the measurement light and the reference light detected by said detection unit.

5. The apparatus according to claim 1, further comprising
an optical element which is inserted both between the measurement target surface and said detection unit and between the reference surface and said detection unit, and configured to split combined light of the measurement light reflected by the measurement target surface and the reference light reflected by the reference surface.

6. The apparatus according to claim 1, wherein
said processing unit obtains, a signal Ir″(Z) in which an influence of a variation in amount of light from the light source, that is contained in the interference signal of the interference pattern, is reduced, in accordance with:
$${Ir}^{″} ( Z ) = \frac{Ir ( Z ) - ( R ( Z ) + M ( Z ) )}{\sqrt{R ( Z ) M ( Z )}}$$
where Ir(Z) is the interference signal of the interference pattern, M(Z) is the intensity of the measurement light, and R(Z) is the intensity of the reference light.

7. The apparatus according to claim 1, wherein
said processing unit Fourier-transforms the interference signal of the interference pattern to obtain a phase component and an amplitude component, and obtains, a signal in which an influence of a variation in amount of light from the light source, that is contained in the interference signal of the interference pattern, is reduced, based on the phase component, the amplitude component, and the intensities of the measurement light and the reference light.

8. A measurement apparatus which measures a shape of a measurement target surface, the apparatus comprising:
an optical system configured to split light from a light source into measurement light and reference light, and combine the measurement light reflected by the measurement target surface and the reference light reference light reflected by a reference surface;
a detection unit configured to detect the measurement light and reference light combined by the optical system; and
a processing unit configured to obtain a shape of the measurement target surface based on an interference signal from the detection unit,
wherein said optical system forms, on a detection surface of the detection unit, at least one of a region where only the measurement light reflected by the measurement target surface enters and a region where only the reference light reflected by the reference surface enters, and a region where both the measurement light reflected by measurement target surface and the reference light reflected by the reference surface enter.

9. An exposure apparatus comprising:
an illumination optical system configured to illuminate a reticle;
a projection optical system configured to project a pattern of the reticle onto a substrate;
a measurement apparatus configured to measure a surface shape of the substrate; and
a stage configured to adjust a position of the substrate based on the surface shape of the substrate measured by said measurement apparatus,
said measurement apparatus including
an optical system configured to split light from a light source into measurement light and reference light, guide the measurement light onto a surface of the substrate, and guide the reference light onto a reference surface,
a detection unit configured to detect an intensity of the measurement light reflected by the surface of the substrate, an intensity of the reference light reflected by the reference surface, and an interference pattern formed between the measurement light reflected by the surface of the substrate and the reference light reflected by the reference surface, and
a processing unit configured to obtain a surface shape of the substrate based on an interference signal of the interference pattern detected by said detection unit,
wherein said processing unit obtains the surface shape of the substrate based on at least one of the intensities of the measurement light and the reference light detected by said detection unit and the interference signal of the interference pattern detected by said detection unit.

10. A device fabrication method comprising steps of:
exposing a substrate using an exposure apparatus; and
performing a development process for the substrate exposed,
wherein the exposure apparatus comprising:
an illumination optical system configured to illuminate a reticle;
a projection optical system configured to project a pattern of the reticle onto the substrate;
a measurement apparatus configured to measure a surface shape of the substrate; and
a stage configured to adjust a position of the substrate based on the surface shape of the substrate measured by said measurement apparatus,
said measurement apparatus including
an optical system configured to split light from a light source into measurement light and reference light, guide the measurement light onto a surface of the substrate, and guide the reference light onto a reference surface,
a detection unit configured to detect an intensity of the measurement light reflected by the surface of the substrate, an intensity of the reference light reflected by the reference surface, and an interference pattern formed between the measurement light reflected by the surface of the substrate and the reference light reflected by the reference surface, and
a processing unit configured to obtain a surface shape of the substrate based on an interference signal of the interference pattern detected by said detection unit,
wherein said processing unit obtains the surface shape of the substrate based on at least one of the intensities of the measurement light and the reference light detected by said detection unit and the interference signal of the interference pattern detected by said detection unit.
